(19) United States
(12) Patent Application Publication
(10) Pub. No.: US 2022/0075978 A1
(43) Pub. Date: Mar. 10, 2022

(54) ULTRASONIC FINGERPRINT RECOGNITION ASSEMBLY AND ELECTRONIC DEVICE

(71) Applicant: JIANGXI OUMAISI MICROELECTRONICS CO., LTD., Nanchang (CN)

(72) Inventor: Xuanxuan LIU, Nanchang (CN)

(21) Appl. No.: 17/527,711

(22) Filed: Nov. 16, 2021

Related U.S. Application Data
(63) Continuation of application No. PCT/CN2019/108571, filed on Sep. 27, 2019.

(30) Foreign Application Priority Data
Jul. 4, 2019 (CN) 201910601095.5

(51) Int. Cl. G06K 9/00; B06B 1/06; H01L 41/193; H01L 41/257; H01L 41/45

(52) U.S. Cl. CPC G06K 9/0002; G06K 9/00053; B06B 1/0688; B06B 2201/70; H01L 41/257; H01L 41/45; H01L 41/193

(57) ABSTRACT

An ultrasonic fingerprint recognition assembly is provided. The ultrasonic fingerprint recognition assembly includes a cover plate, a display panel, and an ultrasonic sensor disposed between the cover plate and the display panel. The ultrasonic sensor includes a thin film transistor (TFT) substrate which is close to the display panel, and a piezoelectric layer and a conductive layer which are disposed on the TFT substrate sequentially. The piezoelectric layer is obtained by mixing a piezoelectric material with an organic solvent, coating a mixture of the piezoelectric material and the organic solvent on a substrate, and conducting crystallization and polarization treatment. The organic solvent includes at least one of: butanone, propylene glycol monomethyl ether acetate, and dimethylacetamide.

### CROSS-REFERENCE TO RELATED APPLICATIONS

This application is a continuation of International Application No. PCT/CN2019/108571, filed on Sep. 27, 2019, which claims priority to Chinese Patent Application No. 201910601095.5, filed on Jul. 4, 2019, the entire disclosures of which are incorporated herein by reference.

### TECHNICAL FIELD

This disclosure relates to the technical field of fingerprint recognition, and in particular to an ultrasonic fingerprint recognition assembly and an electronic device.

### BACKGROUND

At present, mobile phones generally conduct fingerprint unlocking by fingerprint collection in a small specific region of displays, which is unable to realize blind unlocking (fingerprint unlocking by fingerprint collection in any region of displays) and increase application (APP) functions through fingerprint unlocking. In order to meet requirements of full-screen mobile phones and improve user experience of a mobile phone, full-screen fingerprint recognition emerges. However, in current full-screen fingerprint recognition solutions, especially ultrasonic fingerprint recognition solutions, an ultrasonic sensor is disposed below a display screen and a touch screen, which certainly proposes high demand of an ultrasonic penetrability. Therefore, it is extremely urgent to develop a new ultrasonic fingerprint recognition solution for full-screen display.

### SUMMARY

In a first aspect, an ultrasonic fingerprint recognition assembly is provided in the present disclosure. The ultrasonic fingerprint recognition assembly includes a cover plate, a display panel, and an ultrasonic sensor disposed between the cover plate and the display panel. The ultrasonic sensor includes a thin film transistor (TFT) substrate which is close to the display panel, and a piezoelectric layer and a conductive layer which are disposed on the TFT substrate sequentially. The piezoelectric layer is obtained by mixing a piezoelectric material with an organic solvent, coating a mixture of the piezoelectric material and the organic solvent on a substrate, and conducting crystallization and polarization treatment. The organic solvent includes at least one of: butanone, propylene glycol monomethyl ether acetate, and dimethylacetamide.

In a second aspect, a method for manufacturing the ultrasonic fingerprint recognition assembly in the first aspect is provided. The method includes: providing a thin film transistor (TFT) substrate; obtaining a mixed slurry by mixing a piezoelectric material with an organic solvent and coating the mixed slurry on a substrate; obtaining a piezoelectric embryo layer by peeling the mixed slurry after crystallization from the substrate and disposing the piezoelectric embryo layer on the TFT substrate; performing polarization treatment on the piezoelectric embryo layer to obtain a piezoelectric layer; providing a conductive layer on the piezoelectric layer; providing a cover plate on a side of the conductive layer which is away from the piezoelectric layer and providing a display panel on a side of the TFT substrate which is away from the piezoelectric layer.

In a third aspect, an electronic device is provided. The electronic device includes the ultrasonic fingerprint recognition assembly in the first aspect.

### BRIEF DESCRIPTION OF THE DRAWINGS

In order to describe implementations in the present disclosure or technical solutions in related art more clearly, the following will give a brief introduction to the accompanying drawings used for describing the implementations or the related art. The implementations described herein are merely for explaining, rather than limiting, the present disclosure.

FIG. 1 is a schematic structural diagram illustrating an ultrasonic fingerprint recognition assembly provided in implementations of the present disclosure.

### DETAILED DESCRIPTION

Technical solutions in the implementations of the disclosure will be described clearly and completely hereinafter with reference to the accompanying drawings in the implementations of the disclosure. Apparently, the described implementations are merely some rather than all implementations of the disclosure. All other implementations obtained by those of ordinary skill in the art based on the implementations of the disclosure without creative efforts shall fall within the protection scope of the disclosure.

An ultrasonic fingerprint recognition assembly is provided in the present disclosure. An ultrasonic sensor is disposed between a cover plate and a display panel. The ultrasonic sensor is configured to emit and receive an ultrasonic signal, and convert the ultrasonic signal into an electric signal, so as to form a fingerprint recognition image. Because the cover plate has a less thickness, the ultrasonic signal will not be affected by the cover plate and have a great penetrability. In addition, compared with related art, fingerprint recognition will be no longer affected by the display panel, and the speed and accuracy of fingerprint recognition can be increased without improving an ultrasonic penetrability. In this case, a piezoelectric layer has a uniform and consistent light transmittance and excellent light transmission performance, which further improves the speed and accuracy of fingerprint recognition. The ultrasonic fingerprint recognition assembly can be designed as a standardized assembly to realize large-scale applications in different scenes.

In a first aspect, an ultrasonic fingerprint recognition assembly is provided in the present disclosure. The ultrasonic fingerprint recognition assembly includes a cover plate, a display panel, and an ultrasonic sensor disposed between the cover plate and the display panel. The ultrasonic sensor includes a thin film transistor (TFT) substrate which is close to the display panel, and a piezoelectric layer and a conductive layer which are disposed on the TFT substrate sequentially. The piezoelectric layer is obtained by mixing a piezoelectric material with an organic solvent, coating a mixture of the piezoelectric material and the organic solvent on a substrate, and conducting crystallization and polarization treatment. The organic solvent includes at least one of: butanone, propylene glycol monomethyl ether acetate, and dimethylacetamide.

As an implementation, the ultrasonic sensor is disposed between the cover plate and the display panel. The cover plate has a finite thickness, therefore, the ultrasonic signal will not be affected by the cover plate. In this case, compared with related art, fingerprint recognition will be no longer affected by the display panel, therefore, the ultrasonic signal has a great penetrability during fingerprint recognition, and the speed and accuracy of fingerprint recognition can be improved.

As an implementation, the piezoelectric layer is configured for conversion between an electric signal and the ultrasonic signal, and configured to emit and receive the ultrasonic signal. A voltage is formed between the conductive layer and the TFT substrate and applied to the piezoelectric layer, such that the piezoelectric layer plays a role of conversion. In this case, the piezoelectric layer is obtained by mixing the piezoelectric material with the organic solvent, coating a mixture of the piezoelectric material and the organic solvent on the substrate, and conducting crystallization and polarization treatment. The organic solvent includes at least one of: butanone, propylene glycol monomethyl ether acetate, and dimethylacetamide. Therefore, the piezoelectric layer has a uniform and consistent light transmittance and excellent light transmission performance.

As an implementation, the organic solvent includes the butanone and the propylene glycol monomethyl ether acetate. When the organic solvent includes the butanone and the propylene glycol monomethyl ether acetate, a molar ratio of the butanone to the propylene glycol monomethyl ether acetate may be, but is not limited to 1:(1-2). The butanone and the propylene glycol monomethyl ether acetate in this molar ratio make the piezoelectric layer have a uniform thickness, so as to make the piezoelectric layer have the consistent light transmittance.

As an implementation, the piezoelectric material includes at least one of: polyvinylidene fluoride, polytetrafluoroethylene, polycarbonate, polyvinylidene difluoride, and polyvinyl chloride. The piezoelectric material provided in the present disclosure can make the piezoelectric layer have a great piezoelectric effect, a strong signal penetration, and a better light transmittance, so as to help improve recognition effect of the ultrasonic sensor.

As an implementation, a molar ratio of the piezoelectric material to the organic solvent is (0.5-3):1, so as to make a particle size of the piezoelectric material in the piezoelectric layer less than 15 nm (nanometer), improve crystallinity, and improve the light transmittance of the piezoelectric layer. As an implementation, the molar ratio of the piezoelectric material to the organic solvent is (0.8-2.5):1, so as to make the particle size of the piezoelectric material in the piezoelectric layer less than 13 nm, and improve the light transmittance of the piezoelectric layer further.

As an implementation, the crystallization is conducted at 130° C.-150° C. for 0.5 h-5 h so as to make the crystallinity of the piezoelectric layer greater than 68%, reduce the particle size of the piezoelectric material, and improve the light transmittance of the piezoelectric layer. As an implementation, the crystallization is conducted at 135° C.-145° C. for 1 h-4 h so as to make the crystallinity of the piezoelectric layer greater than 70%, and improve the light transmittance of the piezoelectric layer further.

As an implementation, the thickness of the piezoelectric layer is less than 20 μmm (micrometer). As an implementation, the thickness of the piezoelectric layer is less than 10 μm. As an implementation, the thickness of the piezoelectric layer is 1 μm-8 μm. When the thickness of the piezoelectric layer is less than 20 μm, the piezoelectric lay has a better light transmittance and a strong signal penetration ability, and a fingerprint recognition speed is fast, such that recognition effect of a sonic fingerprint sensor can be improved. When the thickness of the piezoelectric layer is less than 10 μm, the recognition effect of the sonic fingerprint sensor can be further improved.

As an implementation, the TFT substrate includes a substrate and multiple TFTs arranged in an array and disposed on the substrate. Specifically, the substrate may be, but is not limited to, a glass substrate provided with a polyethylene terephthalate (PET) film. In the present disclosure, the light transmittance of the substrate can meet actual requirements, and a material of the substrate is not limited.

As an implementation, the thickness of the TFT substrate is 150 μm-500 μm. As an implementation, the thickness of the TFT substrate is 200 μm-450 μm. Specifically, the thickness of the TFT substrate may be, but is not limited to, 150 μm, 180 μm, 220 μm, 290 μm, 350 μm, or 420 μm. The thickness of the TFT substrate does not exceed 500 μm, which plays a better supporting role and ensures a desired light transmittance.

As an implementation, a material of the conductive layer includes at least one of: indium tin oxide (ITO), nano silver, and poly(3,4-ethylenedioxythiophene)-poly(styrene sulfonic acid). The conductive layer is made of a material with a great light transmittance, such that the light transmittance of the conductive layer is improved.

As an implementation, the thickness of the conductive layer is 10 μm-20 μm. As an implementation, the thickness of the conductive layer is 12 μm-17 μm. As an implementation, the thickness of the conductive layer is 13 μm-16 μm. The thinner the conductive layer, the greater the light transmittance.

As an implementation, the display panel has a display region, and an orthographic projection of the ultrasonic sensor on the display panel partially covers or completely covers the display region.

As an implementation, the cover plate has a visible region, and an orthographic projection of the ultrasonic sensor on the cover plate partially covers or completely covers the visible region.

In the present disclosure, when the ultrasonic sensor completely covers the display region of the display panel and/or the ultrasonic sensor completely covers the visible region of the cover plate, full-screen fingerprint recognition can be realized, which is beneficial to blind unlocking and improves user experience. In this case, new software design can be collocated, multiple recognition methods can be utilized, such as single-finger recognition, multi-finger recognition, specific recognition gestures, etc., and corresponding multiple recognition effects can be provided according to the multiple recognition methods. For example, when the ultrasonic fingerprint recognition assembly is applied to a mobile phone, interfaces after the mobile phone is unlocked according to different recognition methods can be different, which brings a new experience to the user.

In the present disclosure, when the ultrasonic sensor partially covers the display region of the display panel and/or the ultrasonic sensor partially covers the visible region of the cover plate, preparation costs of the ultrasonic sensor can be saved.

As an implementation, the cover plate includes a cover plate substrate. The cover plate substrate is at least one of: a transparent glass plate, a transparent ceramic plate, and a transparent organic plate. Furthermore, the cover plate includes an ink layer. The cover plate substrate is provided with the ink layer on a surface of the cover plate substrate which is close to the ultrasonic sensor. Moreover, the ink layer is disposed at a surrounding edge of the cover plate.

As an implementation, the cover plate is provided with a surface treatment layer on a surface of the cover plate which is far away from the ultrasonic sensor. Furthermore, the surface treatment layer includes at least one of: an anti-glare layer, an anti-reflection layer, and an anti-fingerprint layer. In the present disclosure, the surface treatment layer is disposed, such that an ultrasonic recognition assembly have functions of anti-glare, anti-reflection, and anti-fingerprint, such that the display effect of the ultrasonic recognition assembly is improved, and comfort level is improved while the user is using the ultrasonic recognition assembly.

As an implementation, the ultrasonic sensor further includes a first bonding layer. The conductive layer is provided with the first bonding layer on a surface which is close to the cover plate. In addition, the first bonding layer includes a die attach film (DAF). Furthermore, the thickness of the first bonding layer is 30 μm-60 μm. Moreover, the thickness of the first bonding layer is 35 μm-60 μm. In the present disclosure, the first bonding layer is configured to protect the conductive layer from oxidation and to adjust frequency to adapt to different thicknesses of the cover plate.

As an implementation, the ultrasonic fingerprint recognition assembly further includes a circuit board connected with the TFT substrate and the conductive layer respectively. Furthermore, the circuit board is a flexible circuit board. In the present disclosure, the first bonding layer is further configured to compensate for an offset where the circuit board is higher than the conductive layer. In this case, the circuit board is disposed outside a path through which an ultrasonic wave is propagated to a contactable object, the ultrasonic wave does not pass through the circuit board, such that effect of the circuit board on ultrasonic propagation is avoided.

As an implementation, the circuit board is connected with the TFT substrate and the conductive layer respectively through an anisotropic conductive film (ACF) adhesive. In the present disclosure, the circuit board is connected with the ultrasonic sensor through an ACF, so as to form an external mounted recognition module which is attached under the cover plate, and realize a full-screen fingerprint recognition function. In the present disclosure, the ACF has multiple conductive particles which are connected with the circuit board and the TFT substrate, such that the ACF is conductive in a Z-axis direction and insulated in an X-axis direction and a Y-axis direction. The Z-axis direction refers to a thickness direction of the ultrasonic fingerprint recognition assembly. The X-axis direction and the Y-axis direction refer to a length direction and a width direction of the ultrasonic fingerprint recognition assembly respectively.

As an implementation, the ultrasonic fingerprint recognition assembly further includes a driver chip disposed on the circuit board. The driver chip generates a control signal to the ultrasonic sensor, such that the ultrasonic sensor can emit the ultrasonic wave and receive an electric signal which is fed back to realize fingerprint recognition.

As an implementation, the ultrasonic fingerprint recognition assembly further includes a second bonding layer disposed between the ultrasonic sensor and the cover plate, so as to connect the ultrasonic sensor and the cover plate. Furthermore, a material of the second bonding layer includes an optically clear adhesive (OCA). In the present disclosure, the first bonding layer is further configured to compensate for an uneven thickness that may occur when the second bonding layer is directly used, to improve flatness of a plane, and to be more beneficial to ultrasonic wave propagation. In this case, the second bonding layer has a relatively large Young's modulus, for example, the OCA has a large Young's modulus, such that weakening of the ultrasonic signal is avoided.

As an implementation, the ultrasonic fingerprint recognition assembly further includes a third bonding layer disposed between the ultrasonic sensor and the display panel, so as to connect the ultrasonic sensor and the display panel. Furthermore, a material of the third bonding layer includes the OCA.

In the present disclosure, the ultrasonic fingerprint recognition assembly can be designed as a standardized assembly, so as to achieve large-scale applications in different scenes. Specifically, the ultrasonic fingerprint recognition assembly can be, but is not limited to, directly mounted among multiple mobile phone assemblies, so as to achieve assembly of a fingerprint recognition structure in the mobile phone, which can not only improve production efficiency and assembling efficiency, but also simplify a process.

In a second aspect, a method for manufacturing an ultrasonic fingerprint recognition assembly in the first aspect is provided in the present disclosure.

In a third aspect, an electronic device is provided in the present disclosure. The electronic device includes the ultrasonic fingerprint recognition assembly in the first aspect.

The present disclosure has beneficial effects as follows. In the ultrasonic fingerprint recognition assembly provided in the present disclosure, the ultrasonic sensor is disposed between the cover plate and the display panel. The ultrasonic sensor is configured to emit and receive the ultrasonic signal, and convert the ultrasonic signal into the electrical signal, so as to form a fingerprint recognition image. Because the cover plate has a finite thickness, the ultrasonic signal will not be affected by the cover plate and have a great penetrability. In addition, compared with related art, fingerprint recognition is no longer affected by the display panel, and the speed and accuracy of fingerprint recognition can be increased without improving an ultrasonic penetrability. In this case, a piezoelectric layer has a uniform and consistent light transmittance and excellent light transmission performance, which further improves the speed and accuracy of fingerprint recognition. The ultrasonic fingerprint recognition assembly can be designed as a standardized assembly to realize large-scale applications in different scenes. The ultrasonic fingerprint recognition assembly can be used in the electronic device, so as to improve the speed and security of fingerprint recognition of the electronic device.

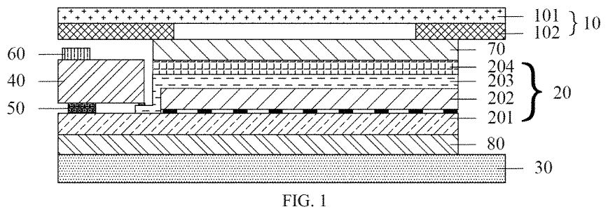

FIG. 1 is a schematic structural diagram illustrating an ultrasonic fingerprint recognition assembly provided in implementations of the present disclosure. As illustrated in FIG. 1, the ultrasonic fingerprint recognition assembly includes a cover plate 10, a display panel 30, and an ultrasonic sensor 20 disposed between the cover plate 10 and the display panel 30. The ultrasonic sensor 20 includes a thin film transistor (TFT) substrate 201 which is close to the display panel 30 and a piezoelectric layer 202 and a conductive layer 203 which are disposed on the TFT substrate 201 sequentially. The piezoelectric layer 202 is obtained by mixing a piezoelectric material with an organic solvent, coating a mixture of the piezoelectric material and the organic solvent on a substrate (i.e., a first substrate), and conducting crystallization and polarization treatment. The organic solvent includes at least one of: butanone, propylene glycol monomethyl ether acetate, and dimethylacetamide.

In implementations of the present disclosure, the ultrasonic sensor 20 is disposed between the cover plate 10 and the display panel 30. The cover plate 10 has a finite thickness, therefore, the ultrasonic signal will not be affected by the cover plate 10. In this case, compared with related art, an ultrasonic signal transmitted during fingerprint recognition is no longer affected by the display panel 30, therefore, the ultrasonic signal has a great penetrability in the process of fingerprint recognition, and speed and accuracy of fingerprint recognition can be improved.

In implementations of the present disclosure, the piezoelectric layer 202 is configured for conversion between electric signal and the ultrasonic signal, and configured to emit and receive the ultrasonic signal. A voltage is formed between the conductive layer 203 and the TFT substrate 201 and is applied to the piezoelectric layer 202, such that the piezoelectric layer 202 conducts conversion between the electric signal and the ultrasonic signal. In this case, the piezoelectric layer 202 is obtained by mixing the piezoelectric material with the organic solvent, coating the piezoelectric material and the organic solvent on a substrate, and conducting crystallization and polarization treatment. The organic solvent includes at least one of: butanone, propylene glycol monomethyl ether acetate, and dimethylacetamide, such that the piezoelectric layer 202 has a uniform and consistent light transmittance and excellent light transmission performance.

In a specific implementation of the present disclosure, the electric signal is propagated to the piezoelectric layer 202 through the TFT substrate 201 and the conductive layer 203, and the ultrasonic signal is formed. The ultrasonic signal is emitted by the piezoelectric layer 202 and penetrates through the cover plate 10. The ultrasonic signal is propagated to a fingerprint ridge and a fingerprint valley, where the ultrasonic signal is reflected to the piezoelectric layer 202. The reflected ultrasonic signal is converted into the electric signal by the conductive layer 203 and TFT substrate 201, and a fingerprint image is obtained.

In implementations of the present disclosure, the organic solvent includes at least one of: butanone, propylene glycol monomethyl ether acetate, and dimethylacetamide. The organic solvent provided in the present disclosure can better dissolve the piezoelectric material, such that the piezoelectric layer 202 has great transparency. Furthermore, the organic solvent includes the butanone and the propylene glycol monomethyl ether acetate. When the organic solvent includes the butanone and the propylene glycol monomethyl ether acetate, a molar ratio of the butanone to the propylene glycol monomethyl ether acetate may be, but is not limited to 1:(1-2). The butanone and the propylene glycol monomethyl ether acetate in this molar ratio make the piezoelectric layer 202 have a uniform thickness, so as to make the piezoelectric layer 202 have the consistent light transmittance. In the present disclosure, a particle size of the piezoelectric material in the piezoelectric layer 202 made by the above method is less than 17 nm, and crystallinity of the piezoelectric material in the piezoelectric layer 202 is greater than 65%, such that the piezoelectric layer 202 has a uniform and consistent light transmittance and excellent light transmission performance.

In implementations of the present disclosure, the piezoelectric material includes at least one of: polyvinylidene fluoride, polytetrafluoroethylene, polycarbonate, polyvinylidene difluoride, and polyvinyl chloride. The piezoelectric material provided in the present disclosure can make the piezoelectric layer 202 have a great piezoelectric effect, a strong signal penetration, and a relatively great light transmittance, so as to help improve recognition effect of the ultrasonic sensor 20.

In a specific implementation of the present disclosure, the piezoelectric layer 202 is obtained by mixing the piezoelectric material and the organic solvent to obtain a mixed slurry, coating the mixed slurry on a substrate, separating the mixed slurry from the substrate after crystallization to obtain a piezoelectric embryo layer, combining the piezoelectric embryo layer with the TFT substrate 201, and conducting polarization treatment.

In implementations of the present disclosure, a molar ratio of the piezoelectric material to the organic solvent is (0.5-3):1, so as to make the particle size of the piezoelectric material 202 in the piezoelectric layer less than 15 nm, improve crystallinity, and improve the light transmittance of the piezoelectric layer. Furthermore, the molar ratio of the piezoelectric material to the organic solvent is (0.8-2.5):1, so as to make the particle size of the piezoelectric material in the piezoelectric layer less than 13 nm, and improve the light transmittance of the piezoelectric layer.

In implementations of the present disclosure, the crystallization is conducted at 130° C.-150° C. for 0.5 h-5 h so as to make the crystallinity of the piezoelectric layer 202 greater than 68%, reduce the particle size of the piezoelectric material, and improve the light transmittance of the piezoelectric layer 202. Furthermore, the crystallization is conducted at 135° C.-145° C. for 1 h-4 h, so as to make the crystallinity of the piezoelectric layer 202 greater than 70%, and improve the light transmittance of the piezoelectric layer. Specifically, the crystallization may be, but is not limited to, conducted at 144° C. for 4 h at 150° C. for 1 h, or at 135° C. for 3 h.

In an implementation of the present disclosure, after the piezoelectric material and the organic solvent are mixed at the molar ratio of (0.5-3):1, the piezoelectric material and the organic solvent are coated on the substrate. After crystallization which is conducted at 130° C.-150° C. for 0.5 h-5 h and polarization treatment, the piezoelectric layer 202 is obtained. In this case, the piezoelectric material in the piezoelectric layer 202 has the particle size of 6 nm-13 nm, and has the crystallinity of 75%-85%. The light transmittance of the piezoelectric layer 202 is greater than 85%.

In an implementation of the present disclosure, after the piezoelectric material and the organic solvent are mixed at the molar ratio of (0.8-2.5):1, the piezoelectric material and the organic solvent are coated on the substrate. After crystallization which is conducted at 135° C.-145° C. for 1 h-4 h and polarization treatment, the piezoelectric layer 202 is obtained. In this case, the piezoelectric material in the piezoelectric layer 202 has the particle size of 8 nm-12 nm, and has the crystallinity of 79%-85%. The light transmittance of the piezoelectric layer 202 is greater than 90%.

In a specific implementation of the present disclosure, after the piezoelectric material and the organic solvent are mixed at the molar ratio of 2:1, the piezoelectric material and the organic solvent are coated on the substrate. After crystallization which is conducted at 144° C. for 4 h and polarization treatment, the piezoelectric layer 202 is obtained. In this case, the piezoelectric material in the piezoelectric layer 202 approximately has the particle size of 10 nm, and has the crystallinity of 82%. The light transmittance of the piezoelectric layer 202 is measured to be greater than 91%.

In implementations of the present disclosure, the thickness of the piezoelectric layer 202 is less than 20 μm. Furthermore, the thickness of the piezoelectric layer 202 is less than 10 μm. Moreover, the thickness of the piezoelectric layer 202 is 1 μm -8 μm. When the thickness of the piezoelectric layer 202 is less than 20 μm, the piezoelectric layer 202 has a great light transmittance and a strong signal penetration ability, a fingerprint recognition speed is fast, such that recognition effect of a sonic fingerprint sensor can be improved. When the thickness of the piezoelectric layer 202 is less than 10 μm, the recognition effect of the sonic fingerprint sensor can be further improved.

In a specific implementation of the present disclosure, preparation of the piezoelectric layer 202 can be, but is not limited to, mixing polyvinylidene fluoride with butanone and propylene glycol monomethyl ether acetate to obtain a mixed slurry; providing a substrate, coating the mixed slurry onto the substrate, and forming a piezoelectric embryo layer on the substrate after crystallization which is conducted at 144° C. for 4 h; peeling the piezoelectric embryo layer from the substrate and placing the piezoelectric embryo layer on the TFT substrate 201, and conducting polarization treatment to obtain the piezoelectric layer 202. The light transmittance of the piezoelectric layer 202 is greater than 91% at a wavelength of 550 nm.

In implementations of the present disclosure, the TFT substrate 201 includes a substrate (i.e., a second substrate) and multiple TFTs arranged in an array and disposed on the substrate. The multiple TFTs arranged in an array are configured to achieve signal detection at various positions of the piezoelectric layer 202, so as to obtain corresponding fingerprint information. Furthermore, the TFT substrate 201 includes a circuit connecting each of multiple TFTs. Specifically, the substrate may be, but is not limited to, a glass substrate provided with a polyethylene terephthalate (PET) film. In the present disclosure, the light transmittance of the substrate can meet actual requirements, and a material of the substrate is not limited.

In implementations of the present disclosure, the thickness of the TFT substrate is 150 μm-500 μm. Furthermore, the thickness of the TFT substrate is 200 μm-450 μm. Specifically, the thickness of the TFT substrate may be, but is not limited to, 150 μm, 180 μm, 220 μm, 290 μm, 350 μm, or 420 μm. As such, the thickness of the TFT substrate 201 is in an appropriate range, such that the TFT substrate 201 can have a relatively great supporting strength, in this case, a relatively great light transmittance can be ensured, and a display image will not be weakened excessively.

In implementations of the present disclosure, a material of the conductive layer 203 includes at least one of: indium tin oxide (ITO), nano silver, and poly(3,4-ethylenedioxythiophene)-poly(styrene sulfonic acid). The conductive layer 203 is made of a material with a high light transmittance, such that the light transmittance of the conductive layer is improved. Specifically, the conductive layer 203 may, but is not limited to, be prepared by a screen-printing silver-paste followed by sintering.

In implementations of the present disclosure, the thickness of the conductive layer 203 is 10 μm-20 μm. Furthermore, the thickness of the conductive layer 203 is 12 μm-17 μm. Moreover, the thickness of the conductive layer is 13 μm-16 μm. Specifically, the thickness of the conductive layer 203 may be, but is not limited to, 11 μm, 14 μm, 14.7 μm, 15 μm or 18.5 μm. The thinner the conductive layer 203, the greater the light transmittance, and the faster the recognition speed.

In implementations of the present disclosure, the display panel 30 has a display region, and an orthographic projection of the ultrasonic sensor 20 on the display panel 30 partially covers or completely covers the display region.

In implementations of the present disclosure, the cover plate 10 has a visible region, and an orthographic projection of the ultrasonic sensor 20 on the cover plate 10 partially covers or completely covers the visible region, in other words, an area of the orthographic projection of the ultrasonic sensor 20 on the cover plate 10 is greater than or equal to an area of the visible region. Furthermore, the orthographic projection of the ultrasonic sensor 20 on the cover plate 10 covers the visible region, the area of the area of the orthographic projection is greater than the area of the visible region, which is further beneficial to full-screen fingerprint recognition.

In implementations of the present disclosure, when the ultrasonic sensor 20 completely covers the display region of the display panel 30 and/or the ultrasonic sensor completely covers the visible region of the cover plate 10, the full-screen fingerprint recognition can be realized, which is beneficial to blind unlocking and improves user experience. In this case, new software design can be collocated, multiple recognition methods can be utilized, such as single-finger recognition, multi-finger recognition, specific recognition gestures, etc., and corresponding multiple recognition effects can be provided according to the multiple recognition methods. For example, when the ultrasonic fingerprint recognition assembly is applied to a mobile phone, interfaces after the mobile phone is unlocked according to different recognition methods can be different. For example, single-finger recognition can show a hidden file, a hidden application (APP), etc., while multi-finger recognition is unable to show hidden files, hidden APPs, etc., which can bring a new experience to users.

In implementations of the present disclosure, when the ultrasonic sensor 20 partially covers the display region of the display panel 30 and/or the ultrasonic sensor 20 partially covers the visible region of the cover plate 10, preparation costs of the ultrasonic sensor 20 can be saved.

As illustrated in FIG. 1, in implementations of the present disclosure, the cover plate 10 includes a cover plate substrate 101. The cover plate substrate 101 is at least one of: a transparent glass plate, a transparent ceramic plate, and a transparent organic plate. Furthermore, the cover plate 10 includes an ink layer 102. The cover plate substrate 101 is provided with the ink layer 102 on a surface of the cover plate substrate 101 which is close to the ultrasonic sensor 20. Moreover, the ink layer 102 is disposed at a surrounding edge of the cover plate 10. In the present disclosure, the cover plate 10 may be a completely transparent component, with the entire cover plate 10 being the visible region, or the cover plate substrate 101 in the cover plate 10 may is provided with the ink layer 102, and a region where is not covered by the ink layer 102 is the visible region. Specifically, the ink layer 102 may be, but is not limited to, disposed on the cover plate substrate 101 through screen printing and the like.

In implementations of the present disclosure, the cover plate 10 is provided with a surface treatment layer on a surface of the cover plate which is far away from the ultrasonic sensor 20. Furthermore, the surface treatment layer includes at least one of: an anti-glare layer, an anti-reflection layer, and an anti-fingerprint layer. In the present disclosure, the surface treatment layer is disposed, such that an ultrasonic recognition assembly have functions of anti-glare, anti-reflection, and anti-fingerprint, such that the display effect of the ultrasonic recognition assembly is improved, and comfort level is improved while the user is using the ultrasonic recognition assembly.

As illustrated in FIG. 1, in implementations of the present disclosure, the ultrasonic sensor 20 further includes a first bonding layer 204. The conductive layer 203 is provided with the first bonding layer 204 on a surface which is close to the cover plate 10. In addition, the first bonding layer 204 includes a die attach film (DAF). Furthermore, the thickness of the first bonding layer 204 is 30 μm-60 μm. Moreover, the thickness of the first bonding layer 204 is 35 μm-60 μm. Specifically, the thickness of the first bonding layer 20 may be, but is not limited to, 33 μm, 38 μm, 43 μm, 47.2 μm, 51 μm, or 55 μm. In the present disclosure, the first bonding layer 204 is configured to protect the conductive layer 203 from oxidation and to adjust frequency to adapt to different thicknesses of the cover plate 10.

In implementations of the present disclosure, the ultrasonic fingerprint recognition assembly further includes a circuit board 40 connected with the TFT substrate 201 and the conductive layer 203 respectively. Furthermore, the circuit board 40 is a flexible circuit board. The first bonding layer 204 is further configured to compensate for an offset where the circuit board 40 is higher than the conductive layer 203. In this case, the circuit board 40 is disposed outside a path through which an ultrasonic wave is propagated to a contactable object, the ultrasonic wave does not pass through the circuit board 40, such that effect of the circuit board 40 on ultrasonic propagation is avoided.

In implementations of the present disclosure, the circuit board 40 is connected with the TFT substrate 201 and the conductive layer 203 respectively through an anisotropic conductive film (ACF) adhesive 50. In the present disclosure, the circuit board 40 is connected with the ultrasonic sensor 20 through an ACF 50, so as to form an external mounted recognition module which is attached between the cover plate 10 and the display panel 30, and realize a full-screen fingerprint recognition function. In the present disclosure, the ACF 50 has multiple conductive particles which are connected with the circuit board 40 and the TFT substrate 201, such that the ACF 50 is conductive in a Z-axis direction and insulated in an X-axis direction and a Y-axis direction.

In implementations of the present disclosure, the ultrasonic fingerprint recognition assembly further includes a driver chip 60 disposed on the circuit board 40. In the present disclosure, the driver chip 60 may be, but is not limited to an application specific integrated circuit (ASIC) chip. The driver chip 60 generates a control signal to the ultrasonic sensor 20, such that the ultrasonic sensor 20 can emit the ultrasonic way and receive an electric signal which is fed back to realize fingerprint recognition.

In implementations of the present disclosure, the ultrasonic fingerprint recognition assembly further includes a second bonding layer 70 disposed between the ultrasonic sensor 20 and the cover plate 10, so as to connect the ultrasonic sensor 20 and the cover plate 10. Furthermore, a material of the second bonding layer 70 includes an optically clear adhesive (OCA). In the present disclosure, the first bonding layer 204 is further configured to compensate for an uneven thickness that may occur when the second bonding layer 70 is directly used, to improve flatness of a plane, and to be more beneficial to ultrasonic wave propagation. In this case, the second bonding layer 70 has a relatively large Young's modulus, for example, the OCA has a large Young's modulus, such that weakening of the ultrasonic signal is avoided.

In implementations of the present disclosure, the ultrasonic fingerprint recognition assembly further includes a third bonding layer 80 disposed between the ultrasonic sensor 20 and the display panel 30, so as to connect the ultrasonic sensor 20 and the display panel 30. Furthermore, a material of the third bonding layer 80 includes the OCA.

In the present disclosure, the light transmittance of the TFT substrate 201, the piezoelectric layer 202, the conductive layer 203, the first bonding layer 204, the second bonding layer 70, and the cover 10 meets requirements of applications, and selection of specific materials is not limited. For example, the light transmittance of the TFT substrate 201, the piezoelectric layer 202, the conductive layer 203, the first bonding layer 204, the second bonding layer 70, and the cover 10 is not less than 85%.

As illustrated in FIG. 1, the ultrasonic fingerprint recognition assembly can work as follows. The fingerprint ridge (skin) in a finger is in direct contact with the ultrasonic fingerprint recognition assembly, and air fills between the fingerprint valley and the ultrasonic fingerprint recognition assembly. Therefore, acoustic impedance values of the ultrasonic wave propagating in the fingerprint ridge and fingerprint valley are different, which generates two different feedback signals. The two different feedback signals are received by the ultrasonic sensor 20, converted into electric signals, and transmitted to the circuit board 40, so as to form a fingerprint recognition image for fingerprint recognition.

An electronic device provided in the present disclosure, includes the above ultrasonic fingerprint recognition assembly.

The ultrasonic fingerprint recognition assembly provided in the present disclosure, may be, but is not limited to, for the electronic device such as a mobile phone, a computer, a tablet computer, an access control system, and the like.

An under-partial display fingerprint recognition solution in the related art needs to open holes in foam, a heat dissipation layer, and electromagnetic interference (EMI), such that integrity of an organic light-emitting diode (OLED) is destroyed. In this case, because the EMI is destroyed, signal interference problems are more likely to occur. When the ultrasonic fingerprint recognition assembly provided in the present disclosure is used for the electronic device, integrity of a display screen can be maintained.

A partial optical under-display (UD) solution in the related art can only be for an OLED screen, and a partial ultrasonic solution is only limited to an OLED soft screen. When the ultrasonic fingerprint recognition assembly provided in the present disclosure is for the electronic device, the ultrasonic fingerprint recognition assembly is not limited by the display screen, the ultrasonic fingerprint recognition assembly can be for a liquid crystal display (LCD) and the OLED, the ultrasonic fingerprint recognition assembly can also be for display screens with Out-cell, On-cell, and In-cell structures.

The ultrasonic fingerprint recognition assembly provided in the present disclosure can realize full-screen unlocking, while the ultrasonic fingerprint recognition assembly can use the full-screen unlocking with new software design to improve user experience, such as supporting blind unlocking with one hand, APP unlocking, multi-finger unlocking, a characteristic point algorithm, and the like, to improve unlocking speed and safety.

The ultrasonic sensor in the ultrasonic fingerprint recognition assembly provided in the present disclosure is directly disposed between the cover plate and the display panel. The cover plate has a finite thickness, therefore, the ultrasonic signal will not be affected by the cover plate. In this case, compared with the ultrasonic sensor disposed under the display panel in the related art, the ultrasonic fingerprint recognition assembly provided in the present disclosure can achieve effect of improving speed and accuracy of the fingerprint recognition without improving penetrability of the ultrasonic wave.

The ultrasonic fingerprint recognition assembly provided in the present disclosure can be designed as a standardized assembly, so as to achieve large-scale applications in different scenes. For example, the ultrasonic fingerprint recognition assembly is directly mounted among multiple mobile phone assemblies, so as to achieve assembly of a fingerprint recognition structure in the mobile phone, which can not only improve production assembly efficiency, but also save a process.

In conclusion, in the ultrasonic fingerprint recognition assembly provided in the present disclosure, the ultrasonic sensor is disposed between the cover plate and the display panel. The ultrasonic sensor is configured to emit and receive the ultrasonic signal, and convert the ultrasonic signal into the electrical signal, so as to form the fingerprint recognition image. Because the cover plate has the finite thickness, the ultrasonic signal will not be affected by the cover plate and have the great penetrability. In addition, compared with the related art, the process of fingerprint recognition is no longer affected by the display panel, and the speed and accuracy of fingerprint recognition can be increased without improving the ultrasonic penetrability. In this case, the piezoelectric layer is obtained by mixing the piezoelectric material with the organic solvent, coating a mixture of the piezoelectric material and the organic solvent on the substrate, and conducting crystallization and polarization treatment. The organic solvent includes at least one of: the butanone, the propylene glycol monomethyl ether acetate, and the dimethylacetamide, such that the piezoelectric layer has the uniform and consistent light transmittance and excellent light transmission performance, and the speed and accuracy of fingerprint recognition is improved. The ultrasonic fingerprint recognition assembly can be designed as the standardized assembly to realize large-scale applications in different scenes. The ultrasonic fingerprint recognition assembly can be for the electronic device, so as to improve fingerprint recognition speed and security of the electronic device.

The above implementations only express several implementations of the present disclosure, and description for the above implementations is relatively specific and detailed, but it should not be understood as a limitation to a scope of a patent of the present disclosure. It should be noted that, for those of ordinary skill in the art, without departing from a concept of the present disclosure, several modifications and improvements can be made, and these all fall within a protection scope of the present disclosure. Therefore, the protection scope of the patent of the present disclosure should be subject to attached claims.

What is claimed is:

1. An ultrasonic fingerprint recognition assembly, comprising:
a cover plate;
a display panel; and
an ultrasonic sensor disposed between the cover plate and the display panel, wherein the ultrasonic sensor comprises a thin film transistor (TFT) substrate which is close to the display panel, and a piezoelectric layer and a conductive layer which are disposed on the TFT substrate sequentially; and wherein the piezoelectric layer is obtained by mixing a piezoelectric material with an organic solvent, coating a mixture of the piezoelectric material and the organic solvent on a substrate, and conducting crystallization and polarization treatment, the organic solvent comprises at least one of: butanone, propylene glycol monomethyl ether acetate, and dimethylacetamide.

2. The ultrasonic fingerprint recognition assembly of claim 1, wherein the cover plate is provided with a surface treatment layer on a surface of the cover plate which is far away from the ultrasonic sensor, and the surface treatment layer comprises at least one of: an anti-glare layer, an anti-reflection layer, and an anti-fingerprint layer.

3. The ultrasonic fingerprint recognition assembly of claim 1, wherein the ultrasonic sensor further comprises a first bonding layer disposed on a side of the conductive layer which is close to the cover plate.

4. The ultrasonic fingerprint recognition assembly of claim 1, further comprising a circuit board connected with the TFT substrate and the conductive layer respectively.

5. The ultrasonic fingerprint recognition assembly of claim 3, further comprising a second bonding layer disposed between the ultrasonic sensor and the cover plate, and the second bonding layer is used to connect the ultrasonic sensor and the cover plate.

6. The ultrasonic fingerprint recognition assembly of claim 5, further comprising a third bonding layer disposed between the ultrasonic sensor and the display panel, and the third bonding layer is used to connect the ultrasonic sensor and the display panel.

7. The ultrasonic fingerprint recognition assembly of claim 1, wherein the organic solvent comprises the butanone and the propylene glycol monomethyl ether acetate, and a molar ratio of the butanone to the propylene glycol monomethyl ether acetate is 1:(1-2).

8. The ultrasonic fingerprint recognition assembly of claim 1, wherein the piezoelectric material comprises at least one of: polyvinylidene fluoride, polytetrafluoroethylene, polycarbonate, polyvinylidene difluoride, and polyvinyl chloride.

9. The ultrasonic fingerprint recognition assembly of claim 1, wherein a molar ratio of the piezoelectric material to the organic solvent is (0.5-3):1.

10. The ultrasonic fingerprint recognition assembly of claim 9, wherein the molar ratio of the piezoelectric material to the organic solvent is (0.8-2.5):1.

11. The ultrasonic fingerprint recognition assembly of claim 10, wherein the molar ratio of the piezoelectric material to the organic solvent is 2:1.

12. The ultrasonic fingerprint recognition assembly of claim 1, wherein the crystallization is conducted at 130° C.-150° C. for 0.5 h-5 h.

13. The ultrasonic fingerprint recognition assembly of claim 12, wherein the crystallization is conducted at 135° C.-145° C. for 1 h-4 h.

14. The ultrasonic fingerprint recognition assembly of claim 13, wherein the condition of the crystallization for applying the mixture of the piezoelectric material and the organic solvent to the substrate is at 144° C. for 4 h.

15. A method for manufacturing an ultrasonic fingerprint recognition assembly, comprising:
providing a thin film transistor (TFT) substrate;
obtaining a mixed slurry by mixing a piezoelectric material with an organic solvent and coating the mixed slurry on a substrate;
obtaining a piezoelectric embryo layer by peeling the mixed slurry after crystallization from the substrate and disposing the piezoelectric embryo layer on the TFT substrate;
performing polarization treatment on the piezoelectric embryo layer to obtain a piezoelectric layer;
providing a conductive layer on the piezoelectric layer; and
providing a cover plate on a side of the conductive layer which is away from the piezoelectric layer and providing a display panel on a side of the TFT substrate which is away from the piezoelectric layer.

16. The method of claim 15, wherein the organic solvent comprises the butanone and the propylene glycol monomethyl ether acetate, and a molar ratio of the butanone to the propylene glycol monomethyl ether acetate is 1:(1-2).

17. The method of claim 15, wherein a molar ratio of the piezoelectric material to the organic solvent is (0.5-3):1.

18. The method of claim 15, wherein the crystallization is conducted at 130° C.-150° C. for 0.5 h-5 h.

19. An electronic device, comprising an ultrasonic fingerprint recognition assembly comprising:
a cover plate;
a display panel; and
an ultrasonic sensor disposed between the cover plate and the display panel, wherein the ultrasonic sensor comprises a thin film transistor (TFT) substrate which is close to the display panel, and a piezoelectric layer and a conductive layer which are disposed on the TFT substrate sequentially.

20. The electronic device of claim 19, wherein the cover plate is provided with a surface treatment layer on a surface of the cover plate which is far away from the ultrasonic sensor, and the surface treatment layer comprises at least one of: an anti-glare layer, an anti-reflection layer, and an anti-fingerprint layer.
